(19) United States
(12) Patent Application Publication
(10) Pub. No.: US 2016/0198072 A1
(43) Pub. Date: Jul. 7, 2016

(54) PCB FOR CAMERA OF VEHICLE VISION SYSTEM

(71) Applicant: MAGNA ELECTRONICS INC., Auburn Hills, MI (US)

(72) Inventor: John T. Wichlacz, Davison, MI (US)

(21) Appl. No.: 14/989,372

(22) Filed: Jan. 6, 2016

Related U.S. Application Data
(60) Provisional application No. 62/100,649, filed on Jan. 7, 2015.

(51) Int. Cl. H04N 5/225; H05K 1/11; H05K 1/03; H05K 1/02

(52) U.S. Cl. CPC H04N 5/2253; H05K 1/0298; H05K 1/111; H05K 1/0306; H05K 2201/012

(57) ABSTRACT

A camera for a vision system of a vehicle includes a printed circuit board having a plurality of layers laminated together. The plurality of layers includes an outermost layer. A pixelated imaging array having a plurality of photosensing elements is disposed at the outermost layer of the plurality of layers of the printed circuit board. The outermost layer has a cutout connecting region to expose electrically conductive pads at a layer below the outermost layer. A discrete flex cable is connected to the electrically conductive pads at the cutout connecting region. The flex cable electrically connects the electrically conductive pads to at least one of (i) circuitry of another printed circuit board of the camera and (ii) circuitry of another printed circuit board of the vision system.

### CROSS REFERENCE TO RELATED APPLICATION

The present application claims the filing benefits of U.S. provisional application Ser. No. 62/100,649, filed Jan. 7, 2015, which is hereby incorporated herein by reference in its entirety.

### FIELD OF THE INVENTION

The present invention relates generally to a vehicle vision system for a vehicle and, more particularly, to a vehicle vision system that utilizes one or more cameras at a vehicle.

### BACKGROUND OF THE INVENTION

Use of imaging sensors in vehicle imaging systems is common and known. Examples of such known systems are described in U.S. Pat. Nos. 5,949,331; 5,670,935 and/or 5,550,677, which are hereby incorporated herein by reference in their entireties. Such cameras include a printed circuit board (PCB), which is an efficient substrate upon which to build an electrical circuit. Depending on the application, different materials and processes will be used. For automotive, FR4, a common fiberglass-based material, has been widely used.

### SUMMARY OF THE INVENTION

The present invention provides a printed circuit board (PCB) that may have components embedded therein and/or may use similar processing to connect multiple boards on the same array with a flexible cable. The present invention may provide a cost-savings opportunity to eliminate rigid-flex on multi-board camera assemblies. The circuit board or boards of the camera comprise a plurality of layers laminated together, with an outermost layer or layers removed at a connecting portion of the board, such that an electrical connector can attach at circuitry at the recessed connecting portion of the circuit board. The recessed connecting portion has exposed circuitry for electrically connecting to the connector, such that the connector may be recessed relative to the outer or upper (or lower) surface of the circuit board.

These and other objects, advantages, purposes and features of the present invention will become apparent upon review of the following specification in conjunction with the drawings.

### BRIEF DESCRIPTION OF THE DRAWINGS

FIG. 1 is a cross-sectional view of a PCB showing a via or passageway through the board;

FIG. 2 is a section of a PCB array showing two instances of a rigid-flex, 2 board example;

FIG. 3 is a view of a chip resistor shown soldered in place within the PCB structure; and

FIG. 4 is a perspective view of a laminated printed circuit board with its last layers modified to expose connection pads in accordance with the present invention.

### DESCRIPTION OF THE PREFERRED EMBODIMENTS

A vehicle vision system and/or driver assist system and/or object detection system and/or alert system operates to capture images exterior of the vehicle and may process the captured image data to display images and to detect objects at or near the vehicle and in the predicted path of the vehicle, such as to assist a driver of the vehicle in maneuvering the vehicle in a rearward direction. The vision system includes an image processor or image processing system that is operable to receive image data from one or more cameras and provide an output to a display device for displaying images representative of the captured image data. Optionally, the vision system may provide a top down or bird's eye or surround view display and may provide a displayed image that is representative of the subject vehicle, and optionally with the displayed image being customized to at least partially correspond to the actual subject vehicle.

The imaging system or vision system includes at least one camera or imaging array sensor, such as one or more interior or exterior facing imaging sensors or cameras. The cameras include a printed circuit board (PCB) and an array of photosensing elements and associated circuitry established at the circuit board to provide a camera chip.

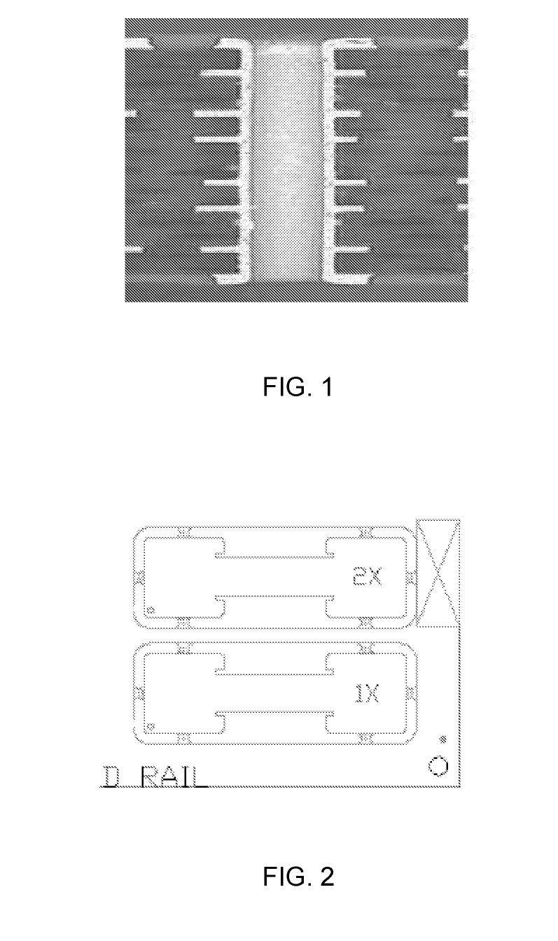

For PCBs of automotive cameras, FR4, a common fiberglass-based material, has been widely used. In the process of forming the board or substrate, multiple layers can be laminated together to provide parallel circuit routing opportunities as well as shielding layers and/or additional current-carrying paths, such as can be seen with reference to FIG. 1. In applications where the circuit packaging requires the use of multiple boards, it may be necessary to pass signals between the boards. Board-to-board connectors can be used which may comprise rigid pins or flexible cables. These are practical for lower-speed signals where there is board space to provide the connectors on each side.

Another method used is rigid-flex technology. This involves laminating one or more layers in the PCB substrate which are made of flexible materials. Doing this requires that all boards that are to be connected must be on the same array (such as shown in FIG. 2).

Because rigid flex technology introduces different materials and processes, it is more expensive than conventional FR4. Depending on the distance between the boards in a rigid-flex configuration, more or less wasted material will be present in the array design, driving costs up further.

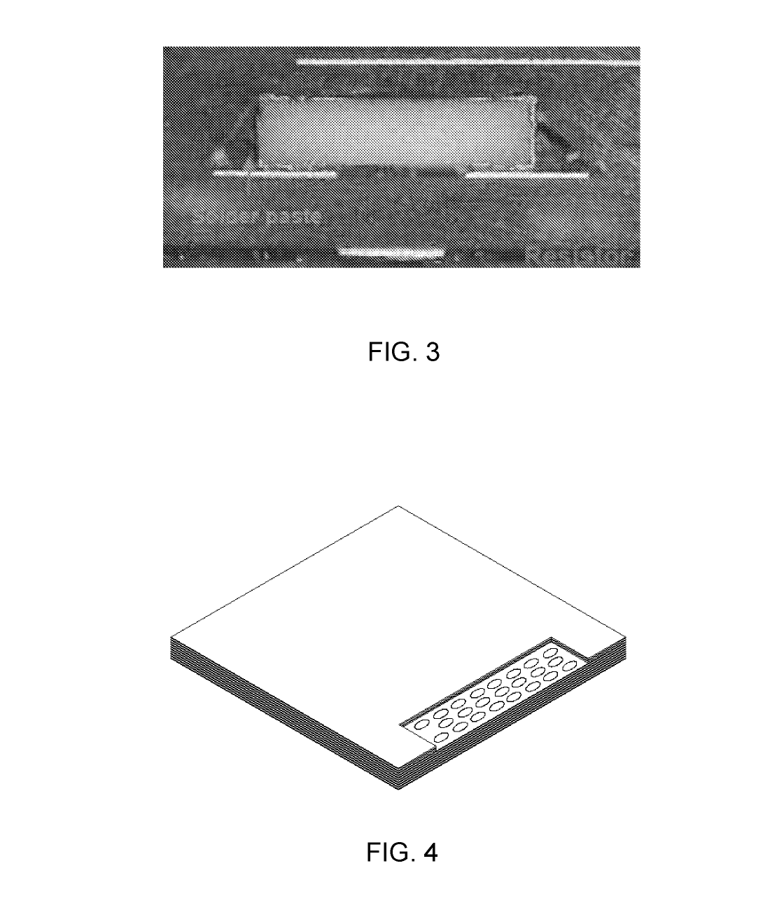

Another emerging technology involves embedding components. In this process, components are introduced to the PCB layers as the layers are being assembled to form the laminated PCB. The layers are electrically connected and tested and captured in the resin layers between fiberglass laminates (such as shown in FIG. 3). This also drives cost through the newer, atypical processes, as compared to simple FR4 construction.

The present invention utilizes post-process bonding of an electrically conducting lead or flex cable between two or more PCBs populated in the same array, during the PCB fabrication or prior to SMT population. At the PCB manufacturer, the boards would follow a traditional FR4 assembly, which would reduce cost. During the assembly of the PCB, the last layers would have a cutout to expose a number of electrical pads (such as shown in FIG. 4). After the array is complete, the PCB supplier or customer can populate a discrete flex cable on the PCB using traditional soldering processes potentially requiring strain-relieving measures such as component underfill.

The expected benefits of the present invention include reduction in waste on the array due to board spacing by avoiding atypical processes. The PCB of the present invention also provides for the flex cable to sit below the top surface of the PCB which would not impede SMT processing, particularly a solder stencil process or the like. The PCB of the present invention also allows for enhanced or superior flex cable design options, and the assembly of the cable can be better controlled than hot-bar soldering techniques. Also, with the PCB of the present invention, there is no need for connectors on the boards. The PCB of the present invention may utilize aspects of the PCBs described in U.S. Publication No. US-2014-0138140, which is hereby incorporated herein by reference in its entirety.

The PCB may be part of a camera for a vehicle, and the circuitry of the PCB may include or be connected with an imaging array of the camera. The camera or sensor may comprise any suitable camera or sensor. Optionally, the camera may comprise a “smart camera” that includes the imaging sensor array and associated circuitry and image processing circuitry and electrical connectors and the like as part of a camera module, such as by utilizing aspects of the vision systems described in International Publication Nos. WO 2013/081984 and/or WO 2013/081985, which are hereby incorporated herein by reference in their entireties.

The system associated with the camera includes an image processor operable to process image data captured by the camera or cameras, such as for detecting objects or other vehicles or pedestrians or the like in the field of view of one or more of the cameras. For example, the image processor may comprise an EyeQ2 or EyeQ3 image processing chip available from Mobileye Vision Technologies Ltd. of Jerusalem, Israel, and may include object detection software (such as the types described in U.S. Pat. Nos. 7,855,755; 7,720,580 and/or 7,038,577, which are hereby incorporated herein by reference in their entireties), and may analyze image data to detect vehicles and/or other objects. Responsive to such image processing, and when an object or other vehicle is detected, the system may generate an alert to the driver of the vehicle and/or may generate an overlay at the displayed image to highlight or enhance display of the detected object or vehicle, in order to enhance the driver's awareness of the detected object or vehicle or hazardous condition during a driving maneuver of the equipped vehicle.

The vehicle may include any type of sensor or sensors, such as imaging sensors or radar sensors or lidar sensors or ladar sensors or ultrasonic sensors or the like. The imaging sensor or camera may capture image data for image processing and may comprise any suitable camera or sensing device, such as, for example, a two dimensional array of a plurality of photosensor elements arranged in at least 640 columns and 480 rows (at least a 640 ×480 imaging array, such as a megapixel imaging array or the like), with a respective lens focusing images onto respective portions of the array. The photosensor array may comprise a plurality of photosensor elements arranged in a photosensor array having rows and columns. Preferably, the imaging array has at least 300,000 photosensor elements or pixels, more preferably at least 500,000 photosensor elements or pixels and more preferably at least 1 million photosensor elements or pixels. The imaging array may capture color image data, such as via spectral filtering at the array, such as via an RGB (red, green and blue) filter or via a red/red complement filter or such as via an RCC (red, clear, clear) filter or the like. The logic and control circuit of the imaging sensor may function in any known manner, and the image processing and algorithmic processing may comprise any suitable means for processing the images and/or image data.

For example, the vision system and/or processing and/or camera and/or circuitry may utilize aspects described in U.S. Pat. Nos. 7,005,974; 5,760,962; 5,877,897; 5,796,094; 5,949,331; 6,222,447; 6,302,545; 6,396,397; 6,498,620; 6,523,964; 6,611,202; 6,201,642; 6,690,268; 6,717,610; 6,757,109; 6,802,617; 6,806,452; 6,822,563; 6,891,563; 6,946,978; 7,859,565; 5,550,677; 5,670,935; 6,636,258; 7,145,519; 7,161,616; 7,230,640; 7,248,283; 7,295,229; 7,301,466; 7,592,928; 7,881,496; 7,720,580; 7,038,577; 6,882,287; 5,929,786 and/or 5,786,772, which are all hereby incorporated herein by reference in their entireties.

Changes and modifications in the specifically described embodiments can be carried out without departing from the principles of the invention, which is intended to be limited only by the scope of the appended claims, as interpreted according to the principles of patent law including the doctrine of equivalents.

1. A camera for a vision system of a vehicle, said camera comprising:
a printed circuit board comprising a plurality of layers laminated together;
wherein said plurality of layers includes an outermost layer;
a pixelated imaging array having a plurality of photosensing elements disposed at said outermost layer of said plurality of layers of said printed circuit board;
wherein said outermost layer comprises a cutout connecting region to expose electrically conductive pads at a layer below said outermost layer; and
an electrically conductive connecting element connected to said electrically conductive pads at said cutout connecting region, wherein said electrically conductive connecting element electrically connects said electrically conductive pads to at least one of (i) circuitry of another printed circuit board of said camera and (ii) circuitry of another printed circuit board of said vision system.

2. The camera of claim 1, wherein said electrically conductive connecting element comprises a flexible cable.

3. The camera of claim 1, wherein said electrically conductive connecting element is connected to said electrically conductive pads using a soldering process.

4. The camera of claim 1, wherein said electrically conductive connecting element is connected to said electrically conductive pads using a strain-relieving measure.

5. The camera of claim 1, wherein said electrically conductive connecting element is connected to said electrically conductive pads using component underfill.

6. The camera of claim 1, wherein said electrically conductive connecting element is disposed below an outer surface of said outermost layer of said printed circuit board.

7. The camera of claim 1, wherein said plurality of layers of said printed circuit board comprise FR4 material.

8. The camera of claim 1, wherein said exposed electrically conductive pads a said cutout connecting region are electrically connected to circuitry of said printed circuit board.

9. The camera of claim 8, wherein said electrically conductive pads are disposed at one of said plurality of layers of said printed circuit board, and wherein said circuitry of said printed circuit board is disposed at at least one other layer of said plurality of layers of said printed circuit board.

10. A camera for a vision system of a vehicle, said camera comprising:
a printed circuit board comprising a plurality of layers laminated together;
wherein said plurality of layers includes an outermost layer;
a pixelated imaging array having a plurality of photosensing elements disposed at said outermost layer of said plurality of layers of said printed circuit board;
wherein said outermost layer comprises a cutout connecting region to expose electrically conductive pads at a layer below said outermost layer;
an electrically conductive connecting element connected to said electrically conductive pads at said cutout connecting region, wherein said electrically conductive connecting element electrically connects said electrically conductive pads to at least one of (i) circuitry of another printed circuit board of said camera and (ii) circuitry of another printed circuit board of said vision system;
wherein said electrically conductive connecting element is disposed below an outer surface of said outermost layer of said printed circuit board; and
wherein said electrically conductive connecting element comprises a flexible cable.

11. The camera of claim 10, wherein said electrically conductive connecting element is connected to said electrically conductive pads using a soldering process.

12. The camera of claim 10, wherein said electrically conductive connecting element is connected to said electrically conductive pads using a strain-relieving measure.

13. The camera of claim 10, wherein said electrically conductive connecting element is connected to said electrically conductive pads using component underfill.

14. The camera of claim 10, wherein said exposed electrically conductive pads a said cutout connecting region are electrically connected to circuitry of said printed circuit board.

15. The camera of claim 14, wherein said electrically conductive pads are disposed at one of said plurality of layers of said printed circuit board, and wherein said circuitry of said printed circuit board is disposed at at least one other layer of said plurality of layers of said printed circuit board.

16. A camera for a vision system of a vehicle, said camera comprising:
a printed circuit board comprising a plurality of layers laminated together;
wherein said plurality of layers of said printed circuit board comprise FR4 material;
wherein said plurality of layers includes an outermost layer;
a pixelated imaging array having a plurality of photosensing elements disposed at said outermost layer of said plurality of layers of said printed circuit board;
wherein said outermost layer comprises a cutout connecting region to expose electrically conductive pads at a layer below said outermost layer;
wherein said exposed electrically conductive pads a said cutout connecting region are electrically connected to circuitry of said printed circuit board;
an electrically conductive connecting element connected to said electrically conductive pads at said cutout connecting region, wherein said electrically conductive connecting element electrically connects said electrically conductive pads to at least one of (i) circuitry of another printed circuit board of said camera and (ii) circuitry of another printed circuit board of said vision system; and
wherein said electrically conductive connecting element is disposed below an outer surface of said outermost layer of said printed circuit board.

17. The camera of claim 16, wherein said electrically conductive connecting element is connected to said electrically conductive pads using a soldering process.

18. The camera of claim 16, wherein said electrically conductive connecting element is connected to said electrically conductive pads using a strain-relieving measure.

19. The camera of claim 16, wherein said electrically conductive connecting element is connected to said electrically conductive pads using component underfill.

20. The camera of claim 16, wherein said electrically conductive pads are disposed at one of said plurality of layers of said printed circuit board, and wherein said circuitry of said printed circuit board is disposed at at least one other layer of said plurality of layers of said printed circuit board.
